(19) United States
(12) Patent Application Publication
(10) Pub. No.: US 2026/0215195 A1
(43) Pub. Date: Jul. 23, 2026

(54) STEALTH WAFER SEPARATION TECHNIQUES FOR WAFER-TO-WAFER BONDING

(71) Applicant: Micron Technology, Inc., Boise, ID (US)

(72) Inventors: Brandon P. Wirz, Boise, ID (US); Andrew M. Bayless, Boise, ID (US); Owen R. Fay, Meridian, ID (US)

(21) Appl. No.: 19/415,166

(22) Filed: Dec. 10, 2025

Related U.S. Application Data
(60) Provisional application No. 63/746,915, filed on Jan. 18, 2025.

(51) Int. Cl. H10P 54/30; H10W 72/00

(52) U.S. Cl. CPC H10P 54/30; H10W 72/07307

(57) ABSTRACT

Stealth wafer separation techniques for wafer-to-wafer bonding (and associated systems, devices, and methods) are disclosed herein. In one embodiment, a method comprises creating, using an infrared (IR) laser, dislocations in a first wafer that delineate a first portion of the first wafer from a second portion of the first wafer; (b) bonding the first portion of the first wafer to a second wafer; and (c) separating the second portion of the first wafer from the first portion generally along the dislocations. The dislocations can include (i) a first array of dislocations that is vertically oriented with respect to the first wafer and/or (ii) a second array of dislocations that is horizontally oriented with respect to the first wafer. The dislocations can be created before or after bonding the first wafer to the second wafer.

### CROSS-REFERENCE TO RELATED APPLICATION(S

The present application claims priority to U.S. Provisional Patent Application No. 63/746,915, filed January 18, 2025, the disclosure of which is incorporated herein by reference in its entirety.

### TECHNICAL FIELD

The disclosed embodiments relate to semiconductor devices. For example, several embodiments of the present technology are directed to stealth wafer separation techniques for use with wafer-to-wafer bonding.

### BACKGROUND

A semiconductor device is an electronic component that relies on the electronic properties of a semiconductor material (primarily silicon, germanium, and gallium arsenide, as well as organic semiconductors) for its function. Semiconductor devices are ubiquitous in modern electronics, powering everything from smartphones to advanced computing systems. As these devices continue to shrink in size and increase in complexity, manufacturers are constantly seeking ways to improve efficiency and reduce costs in the fabrication process.

Silicon wafers are a fundamental component in semiconductor manufacturing, and their efficient use is crucial for maintaining competitive production costs. The semiconductor industry faces ongoing challenges in managing raw material costs and minimizing waste associated with silicon wafers. One area of focus has been reducing waste in the wafer-to-wafer bonding process, which allows for the creation of three-dimensional integrated circuits and other advanced semiconductor structures.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 is a flow diagram illustrating a method for wafer-to-wafer bonding in accordance with various embodiments of the present technology.

FIGS. 2A-2C illustrate partially schematic side views of a first wafer before and after being bonded to a second wafer, in accordance with various embodiments of the present technology.

FIGS. 2D and 2E illustrate partially schematic side views of a second portion of the first wafer of FIGS. 2A-2C after separation from a first portion of the first wafer, in accordance with various embodiments of the present technology.

FIG. 3 is a flow diagram illustrating another method for wafer-to-wafer bonding in accordance with various embodiments of the present technology.

FIGS. 4A and 4B illustrate partially schematic side views of a first wafer bonded to a second wafer, in accordance with various embodiments of the present technology.

FIGS. 4C and 4D illustrate partially schematic side views of a second portion of the first wafer of FIGS. 4A and 4B after separation from a first portion of the first wafer, in accordance with various embodiments of the present technology.

### DETAILED DESCRIPTION

The present disclosure relates generally to stealth wafer separation techniques for use with wafer-to-wafer bonding processes. More specifically, the present disclosure is directed to techniques for separating excess wafer material from a wafer such that the excess wafer material can be used in further processes after the wafer is bonded to another wafer. As a specific example, present wafer-to-wafer bonding processes commonly involve bonding two silicon wafers together and then reducing the thickness of at least one of the wafers using a backgrinding process until only a necessary thickness of silicon remains. Backgrinding removes excess silicon from the top wafer but renders such excess silicon useless for future applications, thereby wasting a large amount of potentially useful material.

To address these concerns, the present technology is generally directed to methods of separating excess portions of silicon (or other wafer material) that are unused in a wafer-to-wafer bonding process, enabling at least part of the excess portions to be used in other processes such as another wafer-to-wafer bonding procedure or as a carrier wafer. For example, several embodiments of the present technology are directed to methods that include creating dislocations in a wafer being used in wafer-to-wafer bonding and separating the wafer generally along the dislocations, enabling a portion of the wafer comprising excess silicon to be reused (e.g., for another wafer-to-wafer bonding procedure or as a carrier wafer). As a specific example, several embodiments of the present technology described herein are directed to creating overlapping arrays of dislocations in a first wafer using an infrared (IR) laser (wherein the dislocations delineate a first and second portion of the first wafer), bonding the first portion of the first wafer to a second wafer, and separating the second portion of the first wafer from the first portion generally along the dislocations. In some embodiments, the separated second portion of the first wafer can be reused as a carrier wafer for other bonding processes, as a test wafer, or for some other purpose. The separated portion of the wafer can be repeatedly separated and reused in the manner described above until the separated portion becomes too thin to be usable. As a result, the present technology is expected to enable the conservation and repeated reuse of excess silicon that would otherwise be wasted during wafer-to-wafer bonding without compromising the bonding process.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. In addition, although many of the embodiments are described below with respect to wafer-to-wafer bonding processes, other applications and other embodiments in addition to those described herein are within the scope of the present technology. For example, unless otherwise specified or made clear from context, the devices, systems, and methods of the present technology can be used for or in combination with other bonding processes, such as substrate-to-substrate bonding processes, chip-to-wafer bonding processes, chip-to-chip bonding processes, stack-to-substrate bonding processes, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

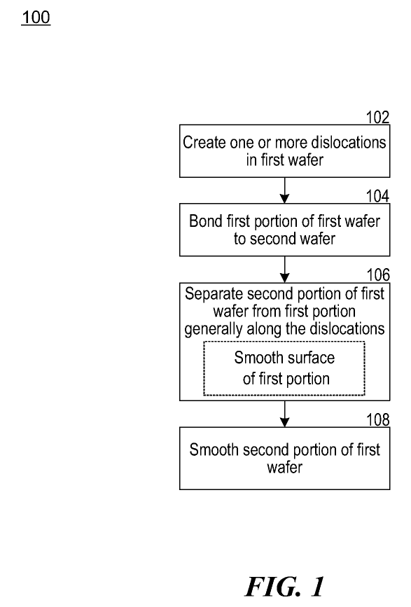

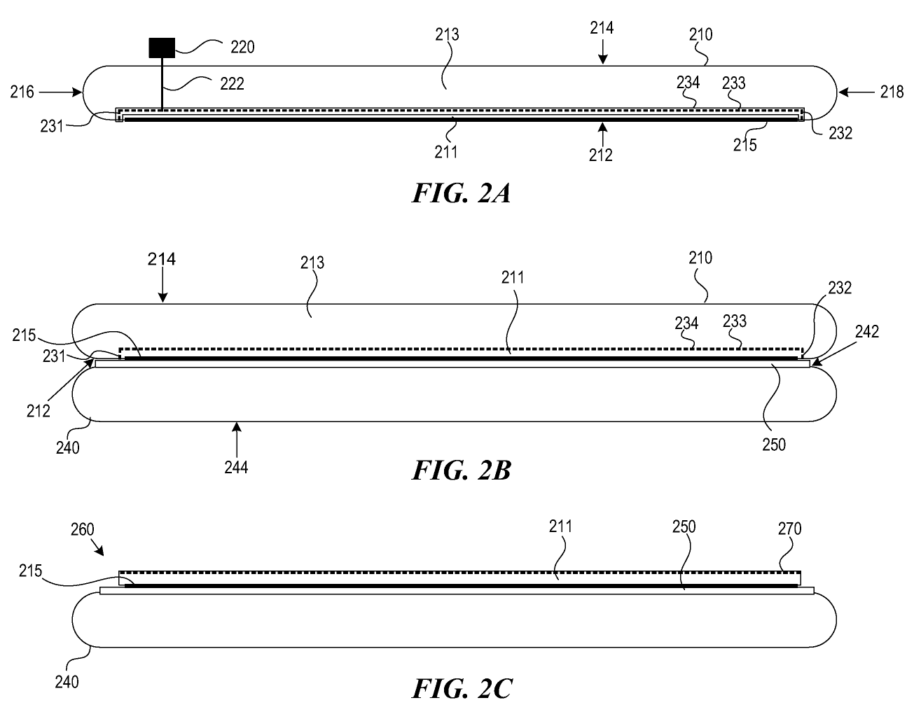

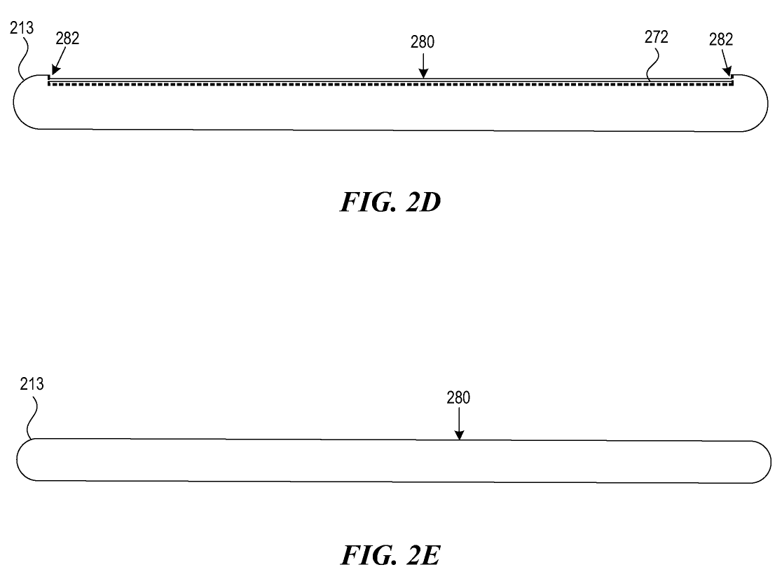

FIG. 1 is a flow diagram illustrating a method 100 for wafer-to-wafer bonding in accordance with various embodiments of the present technology. In some embodiments, the method 100 can be a method for separating an unused portion of a wafer from another portion of the wafer, such as after wafer-to-wafer bonding has been performed. As a specific example, the method 100 can be a method for separating an unused portion of a wafer from another portion of the wafer by creating dislocations in the wafer before wafer-to-wafer bonding. The method 100 is illustrated as a series of steps 102–108 or blocks. All or a subset of one or more of the steps 102–108 can be executed in accordance with the description above and/or with the description that follows. Indeed, several of the steps 102–108 of the method 100 are described in detail below with reference to FIGS. 2A-2E.

The method 100 begins at step 102 by creating one or more dislocations in a first wafer. In some embodiments, creating the one or more dislocations in the first wafer includes creating the one or more dislocations using an IR laser or another suitable means. In these and other embodiments, creating the one or more dislocations in the wafer includes creating a plurality of dislocations along or across the first wafer. For example, creating a plurality of dislocations in the first wafer can include creating an array of dislocations that is vertically oriented with respect to the first wafer. Creating the vertically oriented array of dislocations can include irradiating the first wafer through a front side or a back side of the first wafer and at different depths into the first wafer. As a specific example, creating the vertically oriented array of dislocations can include (a) focusing a focal point of the IR laser at a first location that is a first depth into the first wafer, and (b) irradiating the first wafer such that a lattice defect is created at the first location. Continuing with this specific example, creating the vertically oriented array of dislocations can further include (i) moving (e.g., repositioning, refocusing, translating) the focal point of the IR laser vertically (e.g., directly upwards or downwards with respect to the first location, or in a direction of a plane that is vertically oriented with respect to the first wafer) to a second location that is a second depth into the first wafer different from the first depth, and (ii) irradiating the first wafer such that another lattice defect is created at the second location. In some instances, additional lattice defects can similarly be created at other locations positioned at other depths into the first wafer and such that (a) the dislocation at the first location, (b) the dislocation at the second location, and (c) the additional lattice defects are arranged (e.g., aligned) vertically with one another. Each dislocation of the vertically oriented array can weaken a bond between portions of the wafer positioned on either side of the respective dislocation. As such, the dislocations of the vertically oriented array can allow the wafer to be separated generally along the dislocations of the vertically oriented array via application of a force. In some embodiments, one or more other vertically oriented arrays of dislocations can be formed using a same or similar process, such as at an opposite side of the first wafer (e.g., thereby resulting in a pair of parallel, vertically oriented arrays of dislocations).

As a second specific example, creating a plurality of dislocations in the first wafer can include creating an array of dislocations that is horizontally oriented with respect to the first wafer. Creating the horizontally oriented array of dislocations can include creating dislocations in the first wafer using a same or similar process as described above for creating dislocations to form vertically oriented array dislocations, except that the focal point of the IR laser is moved horizontally along the first wafer instead of vertically. For example, creating a horizontally oriented array of dislocations can include irradiating the first wafer through a front side or a back side of the first wafer and at different locations that are each positioned at a same or similar depth into the first wafer. As a specific example, creating the horizontally oriented array of dislocations can include (a) focusing a focal point of the IR laser at a third location that is a third depth into the first wafer, and (b) irradiating the first wafer such that a lattice defect is created at the third location. Continuing with this specific example, creating the horizontally oriented array of dislocations can further include (i) moving (e.g., repositioning, refocusing, translating) the focal point of the IR laser horizontally (e.g., directly left, directly right, or in a direction of a plane that is horizontally oriented with respect to the first wafer) to a fourth location that is also the third depth into the first wafer, and (ii) irradiating the first wafer such that another lattice defect is created at the fourth location. In some instances, additional lattice defects can similarly be created at other locations positioned generally at the third depth into the first wafer and such that (a) the dislocation at the third location, (b) the dislocation at the fourth location, and (c) the additional lattice defects at the third depth are arranged (e.g., aligned) horizontally with one another. Each dislocation of the horizontally oriented array can weaken a bond between portions of the wafer positioned on either side of the respective dislocation. As such, the dislocations of the horizontally oriented array can allow the wafer to be separated generally along the dislocations of the horizontally oriented array via application of a force. In some embodiments, one or more other horizontally oriented arrays of dislocations can be formed using a same or similar process.

As a third specific example, creating a plurality of dislocations in the first wafer can include creating a diagonal array of dislocations that has a diagonal angle (e.g., an angle having both a nonzero vertical component and nonzero horizontal component) with respect to the first wafer or another reference point. Creating the diagonal array of dislocations can include creating dislocations in the first wafer using a same or similar process as described above for creating dislocations to form vertically and/or horizontally oriented array dislocations, except that the focal point of the IR laser is moved at a diagonal angle (e.g., in a direction not directly vertical or directly horizontal with respect to the first wafer or another reference point) along the first wafer instead of directly vertically or horizontally. As a specific example, creating the diagonal array of dislocations can include (a) focusing a focal point of the IR laser at a fifth location that is a fifth depth into the first wafer, and (b) irradiating the first wafer such that a lattice defect is created at the fifth location. Continuing with this specific example, creating the diagonal array of dislocations can further include (i) moving (e.g., repositioning, refocusing, translating) the focal point of the IR laser diagonally (e.g., at an angle having both a nonzero vertical component and nonzero horizontal component with respect to the first wafer and/or the fifth location) to a sixth location that is a sixth depth into the first wafer, and (ii) irradiating the first wafer such that another lattice defect is created at the sixth location. In some instances, additional lattice defects can similarly be created at other locations positioned generally at different depths into the first wafer and such that (a) the dislocation at the fifth location, (b) the dislocation at the sixth location, and (c) the additional lattice defects at the different depths are arranged (e.g., aligned) diagonally with one another. Each dislocation of the diagonal array can weaken a bond between portions of the wafer positioned on either side of the respective dislocation. As such, the dislocations of the diagonal array can allow the wafer to be separated generally along the dislocations of the diagonal array via application of a force. In some embodiments, one or more other diagonal arrays of dislocations can be formed using a same or similar process, such as at angles that are not parallel to a first diagonal array (e.g., thereby resulting in a pair of diagonal arrays of dislocations, which may or may not intersect on another).

In some embodiments, the plurality of dislocations includes one or more arrays of dislocations that can intersect with one or more other arrays of dislocations formed in the first wafer. For example, in embodiments in which two vertically oriented arrays of dislocations are formed within the first wafer, a horizontally oriented array of dislocations can be formed in the first wafer such that the horizontally oriented array of dislocations spans a horizontal distance across the wafer between the two vertically oriented arrays of dislocations. In another example, two or more diagonal arrays can be formed in the first wafer such that the two or more diagonal arrays intersect. In still another example, one or more diagonal arrays of dislocations are formed in the first wafer, which are intersected by one or more horizontal arrays of dislocations that are formed in the first wafer and/or by one or more vertical arrays of dislocations that are formed in the first wafer. In any of the above examples, the intersecting arrays of dislocations can divide the first wafer into two portions. Therefore, after the arrays of dislocations are created in the first wafer and delineate the two portions of the first wafer, the two portions of the first wafer can be separated from one another generally along the arrays via application of a force.

For the sake of clarity and understanding of step 102 of the method 100 of FIG. 1, consider FIG. 2A that is a partially schematic side view of a first wafer 210 and a laser 220, each configured in accordance with various embodiments of the present technology. As shown, the first wafer 210 includes a frontside 212, a backside 214 opposite the frontside 212, a left side 216, and a right side 218 opposite the left side 216. The first wafer 210 of FIG. 2A further includes metal circuitry 215 positioned at the frontside 212. In other embodiments, the metal circuitry 215 can be omitted or positioned at the backside 214. For example, the first wafer 210 can be a complementary metal oxide semiconductor (CMOS) wafer and/or can include dielectrics, silicon, etc. at the frontside 212 in lieu of the metal circuitry 215.

Referring now to the laser 220, the laser 220 can be an IR laser or another irradiation source. As shown, the laser 220 is positioned at a location above the backside 214 of the first wafer 210. Continuing with the illustrated example, the laser 220 can be configured to emit radiation 222 (e.g., a laser beam) and thereby irradiate the first wafer 210 through the backside 214 of the first wafer 210. More specifically, the laser 220 can be controllable to focus the radiation 222 emitted from the laser 220 at various locations within the first wafer 210 and thereby form dislocations at the various locations within the first wafer 210. As discussed above with reference to step 102 of FIG. 1, the laser 220 can be used to form a plurality of dislocations 234 within the first wafer 210 that are aligned with one another to form one or more arrays of dislocations within the first wafer 210.

For example, as shown in FIG. 2A, the laser 220 can be used to form a first vertically oriented array 231 of one or more dislocations 234, such as by (a) focusing the laser 220 at one or more locations positioned at different depths into the first wafer 210 and proximate the left side 216 of the first wafer 210, and (b) irradiating the first wafer 210 through the backside 214 of the first wafer 210 at the one or more locations proximate the left side 216. Similarly, the laser 220 can be used to form a second vertically oriented array 232 of one or more dislocations 234, such as by (a) focusing the laser 220 at one or more locations positioned at different depths into the first wafer 210 and proximate the right side 218 of the first wafer 210, and (b) irradiating the first wafer 210 through the backside 214 at the one or more locations proximate the right side 218. In addition, the laser 220 can be used to form a horizontally oriented array 233 of one or more dislocations 234, such as by (a) focusing the laser 220 at one or more locations that are each generally positioned a same depth into the first wafer 210, and (b) irradiating the first wafer 210 through the backside 214 of the first wafer 210 at the one or more locations generally positioned at the same depth.

In some embodiments, the first vertically oriented array 231, the second vertically oriented array 232, and/or the horizontally oriented array 233 can be one-dimensional. Additionally, or alternatively, the first vertically oriented array 231, the second vertically oriented array 232, and/or the horizontally oriented array 233 can be multi-dimensional (e.g., two-dimensional). For example, the first vertically oriented array 231 and/or the second vertically oriented array 232 can extend (a) generally vertically with respect to the first wafer 210 as shown in FIG. 2A as well as (b) generally laterally with respect to the first wafer 210, such as in a direction generally into and/or out of the drawings page. In these and other embodiments, the horizontally oriented array 233 can extend (a) generally horizontally with respect to the first wafer 210 as shown in FIG. 2A as well as (b) generally laterally with respect to the first wafer 210, such as in a direction generally into and/or out of the drawings page.

As shown in FIG. 2A, the first and second vertically oriented arrays 231, 232 of dislocations 234 and the horizontally oriented array 233 of dislocations 234 can be formed in the first wafer 210 such that they intersect and/or overlap, dividing the wafer into a first portion 211 and a second portion 213. In some embodiments, the first portion 211 of the wafer 210 can include the metal circuitry 215 and/or can be thinner than, thicker than, or have generally a same thickness as the second portion 213, which can consist of excess wafer material that is not incorporated into a semiconductor device assembly once the first wafer 210 has been bonded to another wafer (as discussed in greater detail below with reference to FIGS. 2B and 2C).

Although irradiating the first wafer 210 is discussed in detail above as involving irradiating the first wafer 210 through the backside 214 of the first wafer 210, the present technology is not so limited. For example, the laser 220 can be positioned below the frontside 212 of the first wafer 210 and used to irradiate portions of the first wafer 210 through the frontside 212, such as in embodiments that omit the metal circuitry 215. In still other embodiments, the laser 220 can be positioned and used to irradiate the first wafer 210 through other sides (e.g., through the left side 216 and/or through the right side 218) of the first wafer 210, and/or at one or more angles other than generally normal/perpendicular to the backside 214 or frontside 212 of the first wafer 210.

Referring again to FIG. 1, the method 100 continues at step 104 by bonding the first wafer to a second wafer. For example, as discussed above, dislocations formed in the first wafer at step 102 may delineate a first portion of the first wafer from a second portion of the first wafer. Continuing with this example, bonding the first wafer to the second wafer at step 104 can include bonding the first portion of the first wafer to the second wafer, such as using a fusion or hybrid bond. Continuing with the same example, the second portion of the first wafer can consist of excess material that is not incorporated into the final system including the first portion of the first wafer and the second wafer. Therefore, the second portion of the first wafer may not be bonded to the second wafer, allowing the second portion of the first wafer to be separated from the first portion via application of a force. In some embodiments, bonding the first wafer to the second wafer can include bonding the first and second wafers together via an intermediate layer or film, such as a dielectric or adhesive. For example, the intermediate layer may be inserted to facilitate bonding the first portion of the first wafer to the second wafer, increase a bonding strength between the first and second wafers, and/or protect metal circuitry formed in the first wafer or the second wafer.

For the sake of clarity and understanding of step 104 of the method 100 of FIG. 1, consider FIG. 2B that is a partially schematic side view of the first wafer 210 of FIG. 2A bonded to a second wafer 240 using a dielectric film 250 in accordance with various embodiments of the present technology. As shown, the second wafer 240 includes a frontside 242 and a backside 244 opposite the frontside 242. In some embodiments, the second wafer 240 further includes various features such as circuitry, memory devices, and/or other semiconductor components (not shown). In other embodiments, the second wafer 240 has few or no features of its own and serves as a carrier or support wafer for the first wafer 210.

Referring now to the dielectric film 250, the dielectric film 250 is disposed between the wafers 210, 240 to facilitate bonding the wafers 210, 240 together. The dielectric film 250 may include materials such as silicon dioxide, silicon nitride, or other suitable dielectric materials. The dielectric film 250 may increase bonding strength between the wafers 210, 240 and/or provide electrical insulation that protects metal circuitry 215 positioned at the frontside 212 of the first wafer from being damaged during or after bonding of the wafers 210, 240. As shown in FIG. 2B, the frontside 212 of the first wafer is bonded to the frontside 242 of the second wafer via the dielectric film 250. The present technology, however, is not so limited. In other embodiments, the two wafers 210, 240 may be bonded by bonding either of the frontside 212 or backside 214 of the first wafer to either of the frontside 242 or backside 244 of the second wafer. Furthermore, in some embodiments, an intermediate film or material other than or in addition to a dielectric film 250 may be placed in between the wafers 210, 240 during bonding (e.g., to assist with bonding the wafers 210, 240 together).

Referring again to FIG. 1, the method 100 continues at step 106 by separating the second portion of the first wafer from the first portion of the first wafer generally along the dislocations formed in the first wafer at step 102. In some embodiments, the portions are separated by applying a force to the second portion of the first wafer. For example, the force may be applied by at least one of a vacuum (e.g., suction applied to the second portion, the second wafer, or both), an edge gripper (e.g., an apparatus that grips and peels the second portion from the first portion), or thermal stress (e.g., a thermal mismatch between the first and second portions of the first wafer). After the second portion of the first wafer is separated from the first portion, the first portion of the first wafer remains bonded to the second wafer, forming a semiconductor device assembly 260.

In some embodiments, imperfections in the wafer lattice left behind by the creation and/or separation of the dislocations may create a gettering layer on the first portion and/or the second portion of the first wafer that reduces the ability of copper or other heavy metal contaminants from spreading throughout the portion of the wafer. For example, a top surface of the first portion of the first wafer (e.g., a surface at a side of the first wafer opposite the second wafer after the second portion of the first wafer has been separated from the first portion) can include a gettering layer that includes or corresponds to a plurality of partial dislocations formed in the wafer lattice generally at the dislocations of the horizontally oriented array of dislocations. In some embodiments, such a gettering layer can be implemented into a final device or system.

In other embodiments, after separating the second portion of the first wafer from the first portion generally along the dislocations, a surface of the first portion corresponding to the dislocations can be smoothed. For example, a surface of the first portion of the first wafer corresponding to dislocations of the horizontally oriented array may be smoothed (e.g., so the first portion can be bonded again, such as to a third wafer). In some embodiments, the surface may be smoothed using chemical mechanical polishing (CMP) or another suitable smoothing means. Additionally, or alternatively, one or more surfaces of the first portion of the first wafer corresponding to dislocations of the vertically oriented array may be smoothed.

For the sake of clarity and understanding of step 106 of the method 100 of FIG. 1, consider FIG. 2C that is a partially schematic side view of a semiconductor device assembly 260 realized after separating the second portion 213 (FIG. 2B) of the first wafer 210 from the first portion 211 generally along the dislocations 234 of the horizontally oriented array 233 (FIG. 2B) and the two vertically oriented arrays 231, 232 (FIG. 2B) in accordance with various embodiments of the present technology. As shown in FIG. 2C, the first portion 211 of the first wafer 210 remains bonded to the second wafer 240 after the second portion 213 is separated. As also shown in FIG. 2C, a top surface of the first portion 211 can include a gettering layer 270 that includes or corresponds to a plurality of partial dislocations formed in the wafer lattice at the general location of the horizontally oriented array 233 (FIG. 2B) of dislocations 234. The gettering layer 270 can be used to reduce the ability of copper or other heavy metal contaminants to spread throughout the first portion 211 of the first wafer 210 and/or to the metal circuitry 215 formed in the first portion 211. In other embodiments, the top surface of the first portion 211 may be smoothed using CMP or another suitable smoothing means. In some such embodiments, the smoothing may eliminate the gettering layer 270 formed at the top surface of the first portion 211.

Referring again to FIG. 1, the method 100 continues at step 108 by smoothing the second portion of the first wafer. In some embodiments, smoothing the second portion of the first wafer can include smoothing a side of the second portion corresponding to where the second portion was separated from the first portion along dislocations formed at step 102. For example, smoothing the second portion can include planarizing or otherwise smoothing the side of the second portion corresponding to where the second portion was separated from the first portion along the dislocations formed at step 102, such as by (a) removing raised edges or ends positioned toward a periphery of the second portion of the first wafer that correspond to where the second portion was separated from the first portion generally along the vertically oriented arrays of dislocations in step 106 and/or (b) removing imperfections and/or roughness on a surface of the side of the second portion corresponding to where the second portion was separated generally along the horizontal array of dislocations in step 106. In some embodiments, smoothing the second portion can include smoothing the second portion such that the second portion can be reused as a carrier wafer (e.g., for other bonding processes), as a test wafer, or for some other purpose (e.g., requiring a smooth wafer surface).

For the sake of clarity and understanding of step 108 of the method 100 of FIG. 1, consider FIGS. 2D and 2E that are partially schematic side views of the second portion 213 of the first wafer 210 of FIGS. 2A and 2B after separation from the first portion 211 (FIG. 2C) of the first wafer 210 and before (FIG. 2D) and after (FIG. 2E) being smoothed. The second portion 213 is illustrated in FIGS. 2D and 2E as having been flipped vertically with respect to its appearance in FIGS. 2A and 2B. Referring first to FIG. 2D, the second portion 213 includes a side 280 having edges or ends 282 and a rough surface 272 (e.g., a gettering layer) corresponding to where the second portion 213 was separated from the first portion 211. More specifically, as shown in FIG. 2D, the side 280 of the second portion 213 is not flat or planar because the second portion 213 was separated from the first portion 211 (FIGS. 2A-2C) generally along the horizontally oriented array 233 of dislocations 234 (FIG. 2A and 2B), which terminated at locations where it intersected the two vertically oriented arrays 231, 232 (FIGS. 2A and 2B) of dislocations 234. Thus, the horizontally oriented array 233 did not span the entire length/width of the second portion 213, leaving behind the edges or ends 282 that are illustrated in FIG. 2B as protruding outwards relative to the rest of the side 280 after the second portion 213 is separated from the first portion 211 generally along the horizontally oriented array 233.

Referring now to FIG. 2E that illustrates the second portion 213 of the first wafer 210 after being smoothed, the side 280 of the second portion 213 is now shown as generally flat or planarized, with the edges or ends 282 and the rough surface 272 shown in FIG. 2D having been smoothed away. In some embodiments, the side 280 of the second portion 213 may be smoothed using CMP or another suitable smoothing process or means. After being smoothed, the thickness of the second portion 213 can be reduced in comparison to the thickness of the second portion 213 shown in FIG. 2D (e.g., just after being separated from the first portion 211).

Although FIGS. 2A-2E are described with reference to vertically oriented arrays 231, 232 and a horizontally oriented array 233 of dislocations, this description is solely for the sake of clarity and understanding and the present technology is not so limited. For example, another type of array of dislocations, such as one or more diagonally oriented arrays, may be formed in the first wafer 210 in addition to or in lieu of the vertically oriented arrays 231, 232 and/or the horizontally oriented array 233, which may intersect or overlap with one another and/or with the vertically oriented arrays 231, 232 and/or the horizontally oriented array 233 to divide the first wafer 210 into a first portion and a second portion.

As noted above with reference to step 108 of FIG. 1, smoothing the second portion 213 (as is shown in FIG. 2E) can allow the second portion 213 to be reused as a carrier wafer (e.g., for other bonding processes), as a test wafer, or for some other purpose. Thus, in some embodiments, after steps 102–108 of the method 100 of FIG. 1 are completed, the method 100 may be repeated using the smoothed second portion 213 as a “first wafer” in order to make further use of the second portion 213. In such embodiments, second dislocations may be created in the smoothed second portion 213 using the laser 220 (FIG. 2A). The second dislocations may include an array of dislocations that is vertically oriented with respect to the second portion 213 , horizontally oriented with respect to the second portion 213, and/or diagonally oriented with respect to the second portion. The second dislocations may be created in the same manner as described in reference to step 102 above and may delineate a third portion of the second portion 213 from a fourth portion of the second portion 213. The second dislocations may include two vertically oriented arrays of dislocations on opposite sides of the second portion 213 that intersect and/or overlap with a horizontally oriented array of dislocations, dividing the second portion 213 into a third portion and fourth portion, in the same manner as shown in reference to FIG. 2A for dividing the first wafer 210 into a first portion 211 and second portion 213. Steps 104 and 106 may then be repeated using the third and fourth portions of the second portion 213 such that the third portion is bonded to a third wafer and the fourth portion is separated from the third portion generally along the second dislocations. Step 108 may then be repeated on the fourth portion such that the fourth portion is smoothed and can itself be reused as a “first wafer.” This method 100 of FIG. 1 can be repeated on portions of the first wafer separated at step 106 and/or smoother at step 108, such as until a separated portion becomes too thin to be usable.

Although the steps 102–108 of the method 100 of FIG. 1 are discussed and illustrated in a particular order, the method 100 is not so limited. In other embodiments, all or a subset of one or more of the steps 102–108 of the method 100 can be performed in a different order. For example, all or a subset of any one or more of the steps 102–108 of the method 100 can be performed before, during, and/or after all or a subset of any one or more of the other steps 102–108 of the method 100. Moreover, a person of ordinary skill in the relevant art will recognize that the illustrated method 100 can be altered and still remain within these and other embodiments of the present technology. For example, all or a subset of one or more of the steps 102–108 of the method 100 illustrated in FIG. 1 can be omitted and/or repeated in some embodiments. As a specific example, step 108 of the method 100 can be omitted in some embodiments of the present technology.

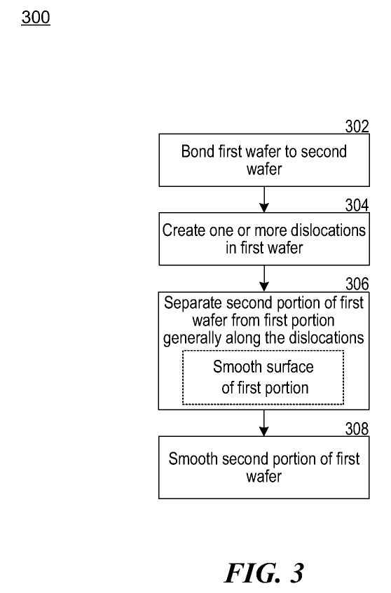

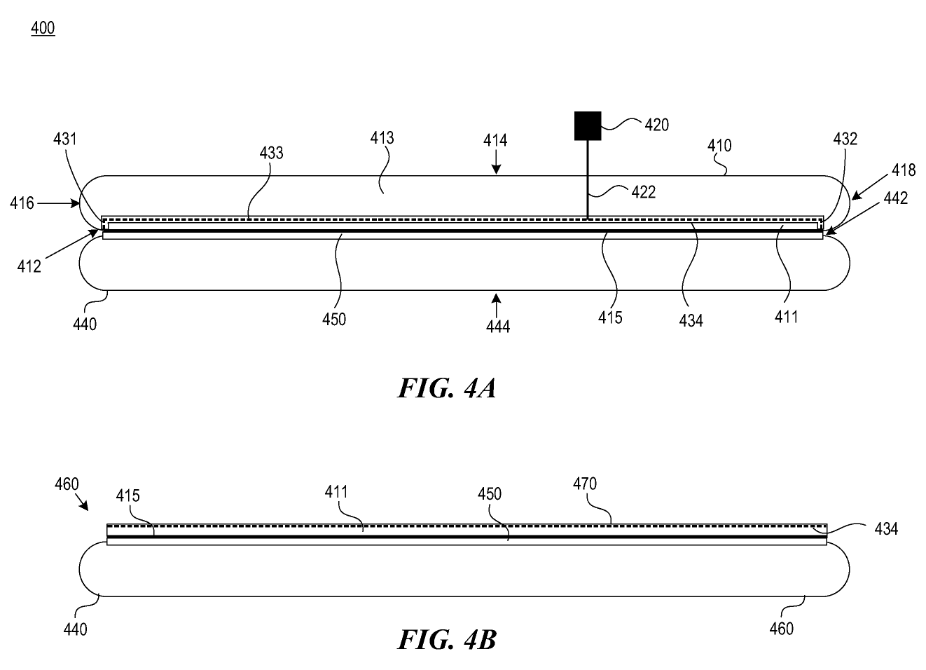

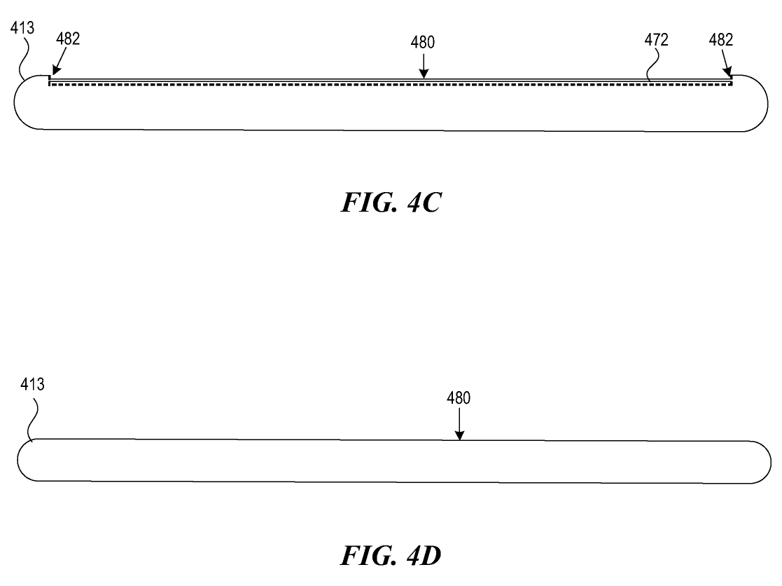

FIG. 3 is a flow diagram illustrating a method 300 for wafer-to-wafer bonding in accordance with various embodiments of the present technology. In some embodiments, the method 300 can be a method for separating an unused portion of a wafer from another portion of the wafer, such as after wafer-to-wafer bonding has been performed. As a specific example, the method 300 can be a method for separating an unused portion of a wafer from another portion of the wafer by creating dislocations in the wafer after wafer-to-wafer bonding. The method 300 is illustrated as a series of steps 302–308 or blocks. All or a subset of one or more of the steps 302–308 can be executed in accordance with the description above and/or with the description that follows. Indeed, several of the steps 302–308 of the method 300 are described in detail below with reference to FIGS. 4A-4D.

The method 300 begins at step 302 by bonding a first wafer to a second wafer. In some embodiments, the first wafer can be bonded to the second wafer in a manner generally consistent with the manner discussed above with reference to step 104 of the method 100 of FIG. 1, except that the first and second wafers can be bonded before formation of vertical and/or horizontal arrays of dislocations in the first wafer. Thus, unlike in the method 100 of FIG. 1, the first wafer can be bonded to the second wafer before delineating a first portion of the first wafer from a second portion of the first wafer.

The method continues at step 304 by creating one or more dislocations in the first wafer. In some embodiments, the one or more dislocations are created in a manner generally consistent with the manner of creating dislocations using an IR laser or another suitable means discussed above with reference to step 102 of the method 100 of FIG. 1, except that the dislocations can be created while the first wafer is bonded to the second wafer. In these and other embodiments, also as discussed above with reference to step 102 of the method 100 of FIG. 1, the dislocations may form intersecting and/or overlapping arrays which divide the first wafer into two portions that can be separated from one another generally along the arrays via application of a force.

For the sake of clarity and understanding of steps 302 and 304 of the method 300 of FIG. 3, consider FIG. 4A that is a partially schematic side view of a laser 420 and a first wafer 410 bonded to a second wafer 440 via a dielectric film 450 in accordance with various embodiments of the present technology. As shown, the first wafer 410 includes a frontside 412, a backside 414 opposite the frontside 412, a left side 416, and a right side 418 opposite the left side 416. The first wafer 410 of FIG. 4A further includes metal circuitry 415 positioned at the frontside 412. In other embodiments, the metal circuitry 415 can be omitted or positioned at the backside 414. For example, the first wafer 410 can be a CMOS wafer and/or can include dielectrics, silicon, etc. at the frontside 412 in lieu of the metal circuitry 415.

Referring now to the laser 420, the laser 420 can be an IR laser or another irradiation source. As shown, the laser 420 is positioned at a location above the backside 414 of the first wafer 410. Continuing with the illustrated example, the laser 420 can be configured to emit radiation 422 in a manner generally consistent with the manner discussed above with reference to FIG. 2A. In some embodiments, the laser 420 can be used to form first and second vertically oriented arrays 431, 432 of dislocations 434 and/or a horizontally oriented array 433 of dislocations 434 in a manner generally consistent with the manner discussed above with reference to FIG. 2A, except that the dislocations 434 are formed after the first wafer 410 is bonded to a second wafer 440.

Referring now to the second wafer 440, the second wafer 440 includes a frontside 442 and a backside 444 opposite the frontside 442. In some embodiments, the second wafer 440 further includes various features such as circuitry, memory devices, and/or other semiconductor components (not shown). In other embodiments, the second wafer 440 has few or no features of its own and serves as a carrier or support wafer for the first wafer 410.

Referring now to the dielectric film 450, the dielectric film 450 is disposed between the wafers 410, 440 to facilitate bonding the wafers 410, 440 together. In some embodiments, the dielectric film 450 may have generally the same features as the dielectric film 250 discussed above with reference to FIG. 2A. As shown in FIG. 4A, the frontside 412 of the first wafer is bonded to the frontside 442 of the second wafer via the dielectric film 450. The present technology, however, is not so limited. In other embodiments, the two wafers 410, 440 may be bonded by bonding either of the frontside 412 or backside 414 of the first wafer to either of the frontside 442 or backside 444 of the second wafer. Furthermore, in some embodiments, an intermediate film or material other than or in addition to a dielectric film 450 may be placed in between the wafers 410, 440 during bonding (e.g., to assist with bonding the wafers 410, 440 together).

Creating dislocations in the first wafer 410 after bonding the first wafer 410 to the second wafer 440 enables different ways of irradiating the first wafer 410 to create dislocations 434 that are not applicable to embodiments where the first wafer 410 is irradiated before bonding, such as the embodiments discussed above with reference to FIGS. 1 and 2A. For example, creating dislocations 434 after bonding can include (i) irradiating the first wafer 410 through the frontside 412 or the backside 414 of only the first wafer 410, or (ii) irradiating through the frontside 412 or the backside 414 of the first wafer 410 in addition to through the second wafer 440. Thus, in embodiments where the frontside 412 of the first wafer 410 is bonded to the frontside 442 or backside 444 of the second wafer 440, the first wafer 410 may be (a) irradiated through only the backside 414 of the first wafer 410, or (b) irradiated through the second wafer 440 and the frontside 412 of the first wafer 410. In embodiments where the backside 414 of the first wafer 410 is bonded to the frontside 442 or backside 444 of the second wafer 440, the first wafer 410 may be (a) irradiated through only the frontside 412 of the first wafer 410, or (b) irradiated through the second wafer 440 and the backside 414 of the first wafer 410.

As shown in FIG. 4A, the first and second vertically oriented arrays 431, 432 of dislocations 434 and the horizontally oriented array 433 of dislocations 434 can be formed in the first wafer 410 such that they intersect and/or overlap, dividing the wafer into a first portion 411 and a second portion 413. In some embodiments, the first portion 411 of the first wafer 410 can include the metal circuitry 415 and/or can be thinner than, thicker than, or have generally a same thickness as the second portion 413, which can consist of excess wafer material that is not incorporated into a semiconductor device assembly formed after the second portion 413 is separated from the first portion 411 (as discussed in greater detail below with reference to FIG. 4B).

Referring again to FIG. 3, the method 300 continues at step 306 by separating the second portion of the first wafer from the first portion of the first wafer generally along the dislocations formed in the first wafer at step 304. In some embodiments, the separation occurs in a manner generally consistent with the manner of separation discussed above with reference to step 106 of the method 100 of FIG. 1 and may likewise include smoothing a surface of the first portion corresponding to the dislocations after separation.

For the sake of clarity and understanding of step 306 of the method 300 of FIG. 3, consider FIG. 4B that is a partially schematic side view of a semiconductor device assembly 460 realized after separating the second portion 413 (FIG. 4A) of the first wafer 410 from the first portion 411 generally along the dislocations 434 in accordance with various embodiments of the present technology. As shown in FIG. 4B, the first portion 411 of the first wafer 410 remains bonded to the second wafer 440 after the second portion 213 is separated. As also shown in FIG. 4B, a top surface of the first portion 411 can include a gettering layer 470, which may have generally the same features as the gettering layer 270 discussed above with reference to FIG. 2C.

Referring again to FIG. 3, the method 300 continues at step 308 by smoothing the second portion of the first wafer. In some embodiments, smoothing the second portion of the first wafer can include smoothing a side of the second portion (a) corresponding to where the second portion was separated from the first portion along the dislocations formed at step 304, and (b) a manner generally similar to the smoothing process discussed above with reference to step 108 of the method 100 of FIG. 1. For example, smoothing the second portion of the first wafer can include smoothing a side of the second portion such that (i) edges/ends, imperfections, roughness, etc. are removed from the side of the second portion corresponding to where the second portion was separated from the first portion along the dislocations formed at step 304 and/or (b) the side is planarized. In some embodiments, smoothing the second portion can include smoothing the second portion such that the second portion can be reused as a carrier wafer (e.g., for other bonding processes), as a test wafer, or for some other purpose (e.g., requiring a smooth wafer surface).

For the sake of clarity and understanding of step 308 of the method 300 of FIG. 3, consider FIGS. 4C and 4D that are partially schematic side views of the second portion 413 of the first wafer 410 of FIG. 4A after separation from the first portion 411 (FIGS. 4A and 4B) of the first wafer 410 and before (FIG. 4C) and after (FIG. 4D) being smoothed. The second portion 413 is illustrated in FIGS. 4C and 4D as having been flipped vertically with respect to its appearance in FIG. 4A. Referring first to FIG. 4C, the second portion 413 includes a side 480 having edges or ends 482 and a rough surface 472 (e.g., a gettering layer) corresponding to where the second portion 413 was separated from the first portion 411. More specifically, as shown in FIG. 4C, the side 480 of the second portion 413 is not flat or planar because the second portion 413 was separated from the first portion 411 (FIGS. 4A and 4B) generally along the horizontally oriented array 433 of dislocations (FIG. 4A), which terminated at locations where it intersected the two vertically oriented arrays 431, 432 (FIG. 4A) of dislocations 434. Thus, the horizontally oriented array 433 did not span the entire length/width of the second portion 413, leaving behind the edges or ends 482 that are illustrated in FIG. 4C as protruding outwards relative to the rest of the side 480 after the second portion 413 is separated from the first portion 411 generally along the horizontally oriented array 433.

Referring now to FIG. 4D that illustrates the second portion 413 of the first wafer 410 after being smoothed, the side 480 of the second portion 413 is now shown as generally flat or planarized, with the edges or ends 482 and the rough surface 472 shown in FIG. 4C having been smoothed away. In some embodiments, the side 480 of the second portion 413 may be smoothed using CMP or another suitable smoothing process or means. After being smoothed, the thickness of the second portion 413 can be reduced in comparison to the thickness of the second portion 413 as shown in FIG. 4C (e.g., just after being separated from the first portion 411).

Although FIGS. 4A-4D are described with reference to vertically oriented arrays 431, 432 and a horizontally oriented array 433 of dislocations, this description is solely for the sake of clarity and understanding and the present technology is not so limited. For example, another type of array, such as one or more diagonally oriented arrays, may be formed in the first wafer 410 in addition to or in lieu of the vertically oriented arrays 431, 432 and/or the horizontally oriented array 433, which may intersect or overlap with one another and/or with the vertically oriented arrays 431, 432 and/or the horizontally oriented array 433 to divide the first wafer 410 into a the first portion and a second portion.

As noted above with reference to step 308 of FIG. 3, smoothing the second portion 413 (as is shown in FIG. 4D) can allow the second portion 413 to be reused as a carrier wafer (e.g., for other bonding processes), as a test wafer, or for some other purpose. Thus, in some embodiments, after steps 302–308 of the method 300 of FIG. 3 are completed, the method 300 may be repeated using the second portion 413 as a “first wafer” in order to make further use of the second portion 413. This repetition can occur in generally the same manner as discussed above with reference to steps 102–108 of FIG. 1 (e.g., with wafer-to-wafer bonding performed after creating dislocations in the second portion 413) and/or can occur in generally the same manner as discussed above with reference to steps 302-308 of FIG. 3 (e.g., with wafer-to-wafer bonding performed before creating dislocations in the second portion 413).

Although the steps 302–308 of the method 300 of FIG. 3 are discussed and illustrated in a particular order, the method 300 is not so limited. In other embodiments, all or a subset of one or more of the steps 302–308 of the method 300 can be performed in a different order. For example, all or a subset of any one or more of the steps 302–308 of the method 300 can be performed before, during, and/or after all or a subset of any one or more of the other steps 302–308 of the method 300. Moreover, a person of ordinary skill in the relevant art will recognize that the illustrated method 300 can be altered and still remain within these and other embodiments of the present technology. For example, all or a subset of one or more of the steps 302–308 of the method 300 illustrated in FIG. 3 can be omitted and/or repeated in some embodiments. As a specific example, step 308 of the method 300 can be omitted in some embodiments of the present technology.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A method, comprising:
creating, using an infrared (IR) laser, dislocations in a first wafer,
wherein the dislocations include (i) a first array of dislocations extending in a first direction and (ii) a second array of dislocations extending in a second direction different from the first direction ,
wherein the dislocations delineate a first portion of the first wafer from a second portion of the first wafer;
bonding the first portion of the first wafer to a second wafer; and
separating the second portion of the first wafer from the first portion generally along the dislocations.

2. The method of claim 1, wherein:
creating the first array of dislocations includes focusing the IR laser at a plurality of different depths into the first wafer; and
creating the second array of dislocations includes focusing the IR laser at a plurality of different locations across the first wafer, each of the different locations positioned a same depth into the first wafer.

3. The method of claim 2, wherein the first array of dislocations is a vertically oriented array of dislocations and the first direction is a vertical direction with respect to the first wafer.

4. The method of claim 1, wherein the first array of dislocations is a diagonally oriented array and the first direction includes a nonzero vertical component and nonzero horizontal component with respect to the first wafer.

5. The method of claim 1, wherein the first array of dislocations and the second array of dislocations intersect to at least partially delineate the first portion of the first wafer from the second portion of the first wafer.

6. The method of claim 1, wherein separating the second portion from the first portion generally along the dislocations includes applying a force to the second portion.

7. The method of claim 1, wherein bonding the first portion of the first wafer to the second wafer includes bonding the first portion of the first wafer to the second wafer after creating the dislocations using the IR laser.

8. The method of claim 1, wherein bonding the first portion of the first wafer to the second wafer includes bonding the first wafer to the second wafer before creating the dislocations using the IR laser.

9. The method of claim 1, wherein creating the dislocations using the IR laser includes irradiating the first wafer through a backside of the first wafer.

10. The method of claim 1, wherein creating the dislocations using the IR laser includes irradiating the first wafer through a frontside of the first wafer.

11. The method of claim 1, wherein bonding the first portion of the first wafer to the second wafer includes fusion bonding the first portion to the second wafer.

12. The method of claim 1, wherein bonding the first portion of the first wafer to the second wafer includes hybrid bonding the first portion to the second wafer.

13. The method of claim 1, wherein creating the second array of dislocations includes forming a gettering layer at a top surface of the first portion of the first wafer.

14. The method of claim 1, further comprising, after separating the second portion of the first wafer from the first portion generally along the dislocations, smoothing a surface of at least one of the first portion or the second portion corresponding to the dislocations.

15. The method of claim 14, wherein the method comprises smoothing the surface of the second portion corresponding to the dislocations, wherein the dislocations are first dislocations, and wherein the method further comprises:
after smoothing the surface of the second portion —
creating, using the IR laser, second dislocations in the first wafer,
wherein the second dislocations include (i) a third array of dislocations, and (ii) a fourth array of dislocations
wherein the third array of dislocations extends in a third direction,
wherein the fourth array of dislocations extends in a fourth direction different from the third direction, and
wherein the second dislocations delineate a third portion of the first wafer from a fourth portion of the first wafer;
bonding the third portion of the first wafer to a third wafer, and
separating the fourth portion of the first wafer from the third portion generally along the second dislocations.

16. The method of claim 14, wherein the method comprises smoothing the surface of the second portion corresponding to the dislocations, and wherein the method further comprises, after smoothing the surface of the second portion, using the first wafer as a carrier wafer.

17. A method, comprising:
bonding a first wafer to a second wafer, wherein the first wafer includes a plurality of dislocations formed therein, wherein the plurality of dislocations includes (i) a first set of dislocations that collectively extend a first depth into the first wafer and (ii) a second set of dislocations that collectively extend laterally across the first wafer, and wherein each dislocation of the second set is positioned at a corresponding location that is the first depth into the first wafer; and
after bonding the first wafer to the second wafer, separating the first wafer generally along the dislocations.

18. The method of claim 17, further comprising forming, using an infrared (IR) laser, the plurality of dislocations within the first wafer, wherein forming the plurality of dislocations includes forming the plurality of dislocations before bonding the first wafer to the second wafer.

19. The method of claim 17, further comprising forming, using an infrared (IR) laser, the plurality of dislocations within the first wafer, wherein forming the plurality of dislocations includes forming the plurality of dislocations after bonding the first wafer to the second wafer.

20. A semiconductor structure, comprising:
a first substrate; and
a second substrate bonded to the first substrate, wherein the second substrate includes a gettering layer on a side of the second substrate opposite the first substrate, and wherein the gettering layer includes a plurality of partial dislocations formed in the side of the second substrate at least in part by irradiating the second substrate using an infrared (IR) laser.
